(19) United States
(12) Patent Application Publication
(10) Pub. No.: US 2026/0122840 A1
(43) Pub. Date: Apr. 30, 2026

(54) Power Conversion System with Liquid Cooling Apparatus

(71) Applicant: AA Power Inc., Boston, MA (US)

(72) Inventor: Qun Lu, Lexington, MA (US)

(21) Appl. No.: 19/373,561

(22) Filed: Oct. 29, 2025

Related U.S. Application Data
(60) Provisional application No. 63/714,390, filed on Oct. 31, 2024.

(51) Int. Cl. H05K 7/20; H05K 7/14

(52) U.S. Cl. CPC H05K 7/20254; H05K 7/14322; H05K 7/20272; H05K 7/20927

(57) ABSTRACT

A system includes a power conversion system connected between a power source and a load, wherein the power conversion system is connected to the power source through a first interface and connected to the load through a second interface, and a housing comprising a front side portion, a rear side portion, a first sidewall portion, a second sidewall portion, a bottom case portion and a top case portion, wherein the power conversion system is placed inside the housing, at least one of the first sidewall portion, the second sidewall portion, the bottom case portion and the top case portion comprises a channel through which coolant flows to cool heat generating components of the power conversion system, liquid interface ports are placed adjacent to the front side portion, and the first interface and the second interface are placed adjacent to the rear side portion.

### PRIORITY

This application claims the benefit of U.S. Provisional Application No. 63/714,390, filed on Oct. 31, 2024, entitled “Power Conversion System with Liquid Cooling Apparatus,” which application is hereby incorporated herein by reference.

### TECHNICAL FIELD

The present invention relates to a power conversion system, and in particular to a power conversion system with a liquid cooling apparatus.

### BACKGROUND

As technologies further advance, a modern data center is equipped with numerous high-performance processors such as graphics processing units (GPUs). The processors are designed to handle intensive computing workloads such as artificial intelligence (AI) training, machine learning, and complex simulations. These GPUs, often organized into high-density racks, deliver exceptional parallel processing power, enabling the rapid analysis and processing of vast amounts of data.

In a data center, a processor is powered by a power conversion system. This power conversion system is connected between the electric grid and the processor. The power conversion system is configured to convert the ac voltage of the electric grid into a voltage suitable for driving the processor. In operation, the power conversion system produces excess heat, which is commonly released into the surrounding atmosphere for dissipation. Heat dissipation occurs until a component reaches thermal equilibrium. In other words, its temperature stabilizes. At this equilibrium temperature, the rate of heat dissipation matches the rate of heat production, resulting in a constant temperature. Therefore, the temperature remains unchanged over time. In some operating conditions, the heat generated by the power conversion system cannot be fully dissipated. The extra heat causes a high operating temperature. The excessively high operating temperature has a tendency to degrade components and reduce the lifespan of the power conversion system. A recognized solution for operation in the high temperature involves cooling the power conversion system using a liquid, which lowers its temperature to achieve thermal equilibrium.

A liquid-cooled power conversion system is employed to provide power for a high-performance and densely packed data center. In operation, the power conversion system generates heat. The heat is generated primarily from electrical components such as transformers, inductors, capacitors, and power switches. This heat needs to be efficiently removed to prevent overheating. A liquid-cooled plate is designed to be in direct contact with the power supply. The plate is typically made of thermally conductive materials such as copper, aluminum and the like. The thermally conductive materials can efficiently transfer heat from the power supply to the liquid-cooled plate. Inside the liquid-cooled plate, there are channels through which a coolant (e.g., water) circulates. As the heat is transferred from the power supply to the liquid-cooled plate, the coolant absorbs this heat. The heated coolant is then circulated out of the liquid-cooled plate and into the broader liquid cooling loop of the rack. This loop may include a heat exchanger dissipating the heat from the coolant to the outside environment. The cooled liquid then returns to the liquid-cooled plate to absorb more heat. The cooling process forms a continuous cooling cycle. This cooling process keeps the power conversion system at a safe operating temperature under various operating conditions.

### SUMMARY

These and other problems are generally solved or circumvented, and technical advantages are generally achieved, by preferred embodiments of the present disclosure which provide a power conversion system with a liquid cooling apparatus.

In accordance with an embodiment, a system comprises a power conversion system configured to be connected between a power source and a load, wherein the power conversion system is connected to the power source through a first interface, and the power conversion system is connected to the load through a second interface, and a housing comprising a front side portion, a rear side portion, a first sidewall portion, a second sidewall portion, a bottom case portion and a top case portion, wherein the power conversion system is placed inside the housing, at least one of the first sidewall portion, the second sidewall portion, the bottom case portion and the top case portion comprises a channel through which coolant flows to cool heat generating components of the power conversion system, liquid interface ports are placed adjacent to the front side portion, and the first interface and the second interface are placed adjacent to the rear side portion.

In accordance with another embodiment, a power shelf comprises a power supply unit configured to convert electrical power between a power source and a load, at least two capacitor modules disposed adjacent to the power supply unit, and a liquid-cooled sidewall structure positioned between the power supply unit and each of the capacitor modules, the liquid-cooled sidewall structure comprising two parallel sidewalls each having an internal coolant channel configured to absorb heat generated by the power supply unit and the capacitor modules.

In accordance with yet another embodiment, a liquid-cooled power supply unit comprises a power conversion system comprising a plurality of magnetic devices, a plurality of power switches, wherein the power conversion system is connected to a power source through a first electrical connector, and the power conversion system is connected to a load through a second electrical connector, and a housing comprising a front side portion, a rear side portion, a first sidewall portion, a second sidewall portion, a bottom case portion and a top case portion, wherein the power conversion system is placed inside the housing, at least one of the first sidewall portion, the second sidewall portion, the bottom case portion and the top case portion comprises a channel through which coolant flows to cool the plurality of magnetic devices and the plurality of power switches, a liquid inlet and a liquid outlet are placed adjacent to the front side portion, and the first electrical connector and the second electrical connector are placed adjacent to the rear side portion.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a front side perspective view and a rear side perspective view of a power supply unit in accordance with various embodiments of the present disclosure;

FIG. 2 illustrates a rear side view, a top side view, a front side view, a left side view and a bottom side view of the power supply unit shown in FIG. 1 in accordance with various embodiments of the present disclosure;

FIG. 3 is similar to FIG. 2 except that in the top side view, the top case of the power unit has been removed;

FIG. 4 illustrates a rear perspective view of the power unit in accordance with various embodiments of the present disclosure;

FIG. 5 illustrates a front perspective view of the power unit in accordance with various embodiments of the present disclosure;

FIG. 6 illustrates an exploded view of the interior of the power supply unit in accordance with various embodiments of the present disclosure;

FIG. 7 illustrates a cutaway view of the left cold plate in accordance with various embodiments of the present disclosure;

FIG. 8 illustrates a cutaway view of the right cold plate in accordance with various embodiments of the present disclosure;

FIG. 9 illustrates a perspective view of the cold plates in accordance with various embodiments of the present disclosure;

FIG. 10 illustrates an implementation of the left cold plate in accordance with various embodiments of the present disclosure;

FIG. 11 illustrates an implementation of the right cold plate in accordance with various embodiments of the present disclosure;

FIG. 12 illustrates a connecting channel placed between the left cold plate and the right cold plate in accordance with various embodiments of the present disclosure;

FIG. 13 illustrates an integrated tube in accordance with various embodiments of the present disclosure;

FIG. 14 illustrates a top case portion of the housing in accordance with various embodiments of the present disclosure;

FIG. 15 illustrates a bottom case portion of the housing in accordance with various embodiments of the present disclosure;

FIG. 16 illustrates a first cooling implementation of the housing in accordance with various embodiments of the present disclosure;

FIG. 17 illustrates a second cooling implementation of the housing in accordance with various embodiments of the present disclosure;

FIG. 18 illustrates a third cooling implementation of the housing in accordance with various embodiments of the present disclosure;

FIG. 19 illustrates a fourth cooling implementation of the housing in accordance with various embodiments of the present disclosure;

FIG. 20 illustrates a fifth cooling implementation of the housing in accordance with various embodiments of the present disclosure;

FIG. 21 illustrates a sixth cooling implementation of the housing in accordance with various embodiments of the present disclosure;

FIG. 22 illustrates a seventh cooling implementation of the housing in accordance with various embodiments of the present disclosure;

FIG. 23 illustrates an eighth cooling implementation of the housing in accordance with various embodiments of the present disclosure;

FIG. 24 illustrates a first implementation of the sidewall portion in accordance with various embodiments of the present disclosure;

FIG. 25 illustrates a second implementation of the sidewall portion in accordance with various embodiments of the present disclosure;

FIG. 26 illustrates a third implementation of the sidewall portion in accordance with various embodiments of the present disclosure;

FIG. 27 is a perspective view of a power shelf in accordance with various embodiments of the present disclosure;

FIG. 28 is a perspective view of the power shelf after the top case has been removed in accordance with various embodiments of the present disclosure;

FIG. 29 is a perspective view of the power shelf after all components except the liquid-cooled sidewall structure have been removed in accordance with various embodiments of the present disclosure; and

FIG. 30 is an exploded view of the power shelf in accordance with various embodiments of the present disclosure.

Corresponding numerals and symbols in the different figures generally refer to corresponding parts unless otherwise indicated. The figures are drawn to clearly illustrate the relevant aspects of the various embodiments and are not necessarily drawn to scale.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

Further, one or more features from one or more of the following described embodiments may be combined to create alternative embodiments not explicitly described, and features suitable for such combinations are understood to be within the scope of this disclosure. It is therefore intended that the appended claims encompass any such modifications or embodiments.

The present disclosure will be described with respect to preferred embodiments in a specific context, namely a liquid cooling apparatus in a power conversion system connected between an ac power source and a load. The disclosure may also be applied, however, to a variety of power conversion systems. Hereinafter, various embodiments will be explained in detail with reference to the accompanying drawings.

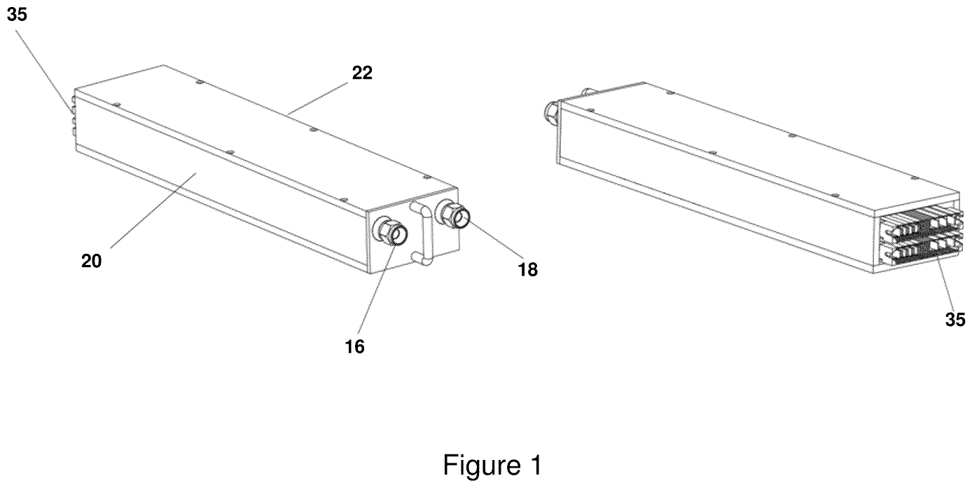

FIG. 1 illustrates a front side perspective view and a rear side perspective view of a power supply unit in accordance with various embodiments of the present disclosure. The power supply unit is a liquid-cooled power supply unit. The left side shows the front side perspective view of the power supply unit. The right side shows the rear side perspective view of a power supply unit.

The power supply unit comprises a power conversion system configured to be connected between a power source and a load. The power supply unit includes a housing, which has a front end and a rear end. Throughout the description, the front end may be alternatively referred to as a front side portion. The rear end may be alternatively referred to as a rear side portion.

At the front end, there are a housing inlet 16 for cooling fluid to enter and a housing outlet 18 for the fluid to exit after absorbing heat generated within the housing. Throughout the description, the term liquid or fluid is used interchangeably to refer to the coolant circulating through the power supply unit.

An external pump supplies the energy necessary to drive the fluid flow from the housing inlet, through the housing, and out the housing outlet. The housing contains two cold plates, a left cold plate 20 and a right cold plate 22, that extend longitudinally from the rear end to the front end. The housing inlet and outlet are connected to the left and right cold plates, respectively, allowing fluid flow between them. At the rear end, there are a plurality of electrical connectors 35. In some embodiments, the power conversion system is connected to the power source through a first electrical connector. The power conversion system is connected to the load through a second electrical connector. Throughout the description, the first electrical connector is alternatively referred to as a first interface. The second electrical connector is alternatively referred to as a second interface.

In operation, the power supply unit shown in FIG. 1 handles high levels of electrical current through electrical connectors located at the rear end. These electrical connectors contain conductors that carry current, which results in ohmic heating as current flows through them. The heating increases with current density, which is the amount of current passing through a given area of the conductor. Since ohmic heating is directly related to current density, larger connectors are beneficial as they reduce current density by distributing the current over a larger surface area. This, in turn, minimizes heating and reduces ohmic losses.

The use of these larger electrical connectors requires significant space at the rear end. In traditional air-cooled power supplies, much of this space is occupied by air vents, limiting the size of the connectors. However, since the power supply unit shown in FIG. 1 is liquid-cooled, the need for bulky air vents is eliminated, freeing up space for larger connectors. Additionally, to further optimize space, the housing inlet and outlet are placed at the front end as shown in FIG. 1, increasing the available contiguous area and allowing for even larger connectors, thereby reducing ohmic heating losses.

As shown in FIG. 1, the inlet 16 and outlet 18 are placed adjacent to the front end of the power supply unit. The connectors 35 or power interfaces are placed adjacent to the rear end of the power supply unit. This configuration is able to separate the liquid interfaces from the electrical interfaces. Advantages of isolating liquid and electrical interfaces include the following: first, placing liquid and electrical connectors at opposite ends of the power supply unit physically separates them, preventing electrical damage caused by connector leakage. Second, positioning the electrical connector at one end of the power supply unit allows for better use of space, enabling the use of larger connectors to meet higher current-carrying demands. Third, placing the electrical connector at one end of the power supply unit makes hot-swapping easier, reducing the precision requirements for alignment. Fourth, placing the inlet and outlet at the front end of the power supply unit makes liquid pipe installation easier, reducing the possibility of liquid leakage. Fifth, the inlet and outlet at the front end make them easily accessible and such easy access allows the low-cost connection components to be used for connecting the liquid pipes and the inlet and outlet.

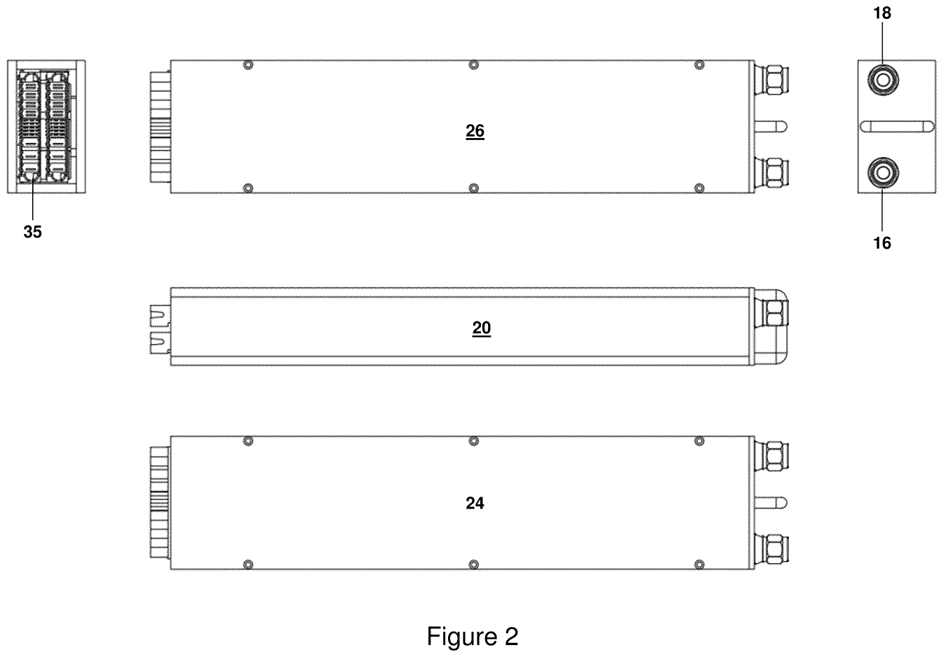

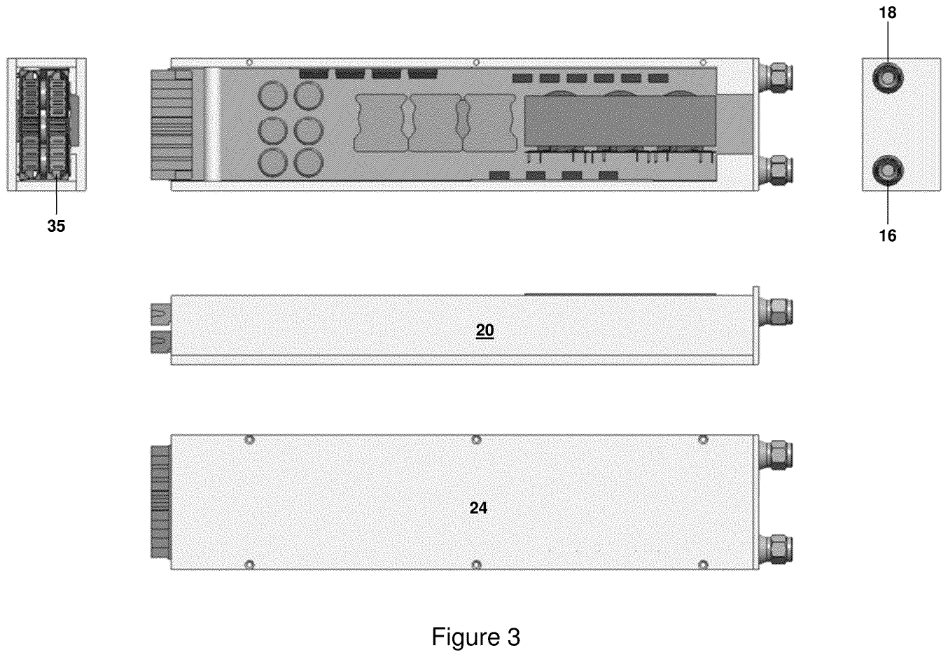

FIG. 2 illustrates a rear side view, a top side view, a front side view, a left side view and a bottom side view of the power supply unit shown in FIG. 1 in accordance with various embodiments of the present disclosure. FIG. 3 is similar to FIG. 2 except that in the top side view, the top case of the power unit has been removed. The left upper corner shows the rear side view of the power supply unit. The upper portion shows the top side view of the power supply unit. The right upper corner shows the front side view of the power supply unit. The middle portion shows the left side view of the power supply unit. The lower portion shows the bottom view of the power supply unit.

As shown in FIG. 2, the electrical connectors 35 are placed at the rear end of the housing. More particularly, the rear side view further illustrates that the electrical connectors 35 occupy substantially all the area of the rear end of the housing. An inlet 16 and an outlet 18 are arranged at an upper portion of the front end of housing of the power supply unit to enable liquid circulation through internal cooling channels adjacent to the heat generating components. In some embodiments, the components that dissipate heat (e.g., transformers, inductors, capacitors, power switches) are referred to herein as heat generating components. Throughout the description, the inlet 16 may be alternatively referred to as a liquid inlet, a housing inlet or a first plate inlet. The coolant outlet 18 may be alternatively referred to as a liquid outlet, a housing outlet or a second plate outlet.

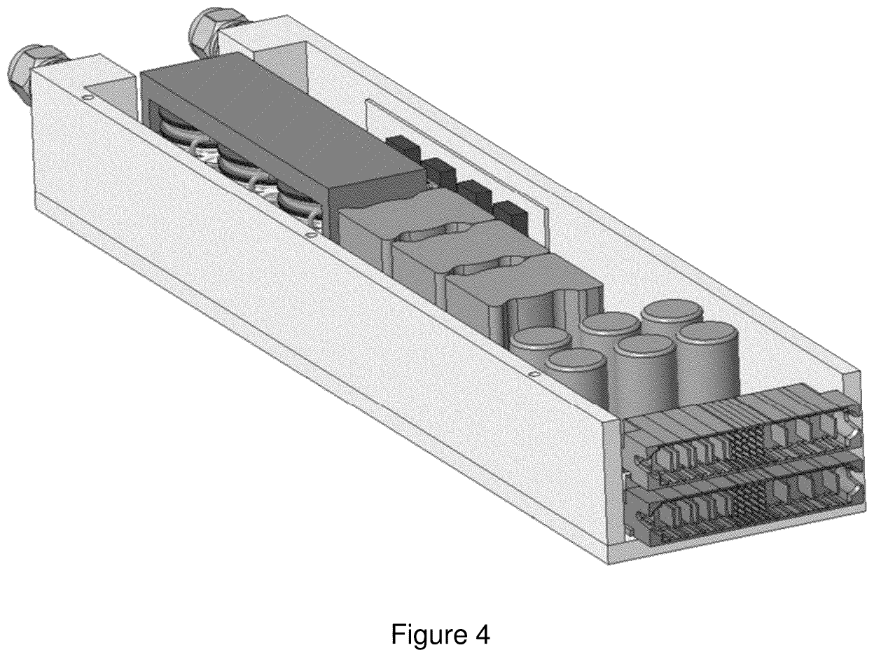

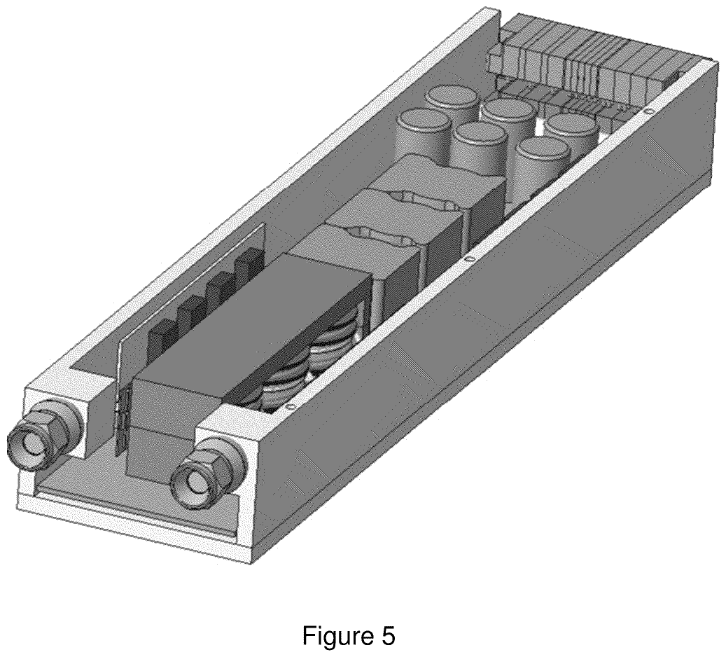

FIG. 4 illustrates a rear perspective view of the power unit in accordance with various embodiments of the present disclosure. FIG. 5 illustrates a front perspective view of the power unit in accordance with various embodiments of the present disclosure. The power supply unit represents a liquid-cooled power conversion system configured for high-power applications. The power unit includes a housing that encloses one or more power conversion modules, such as DC/DC converters, transformers, inductors, capacitors, and switching components that generate significant heat during operation. The housing is generally formed of thermally conductive materials to facilitate efficient heat dissipation and may integrate fluid channels or cold-plate structures for liquid cooling.

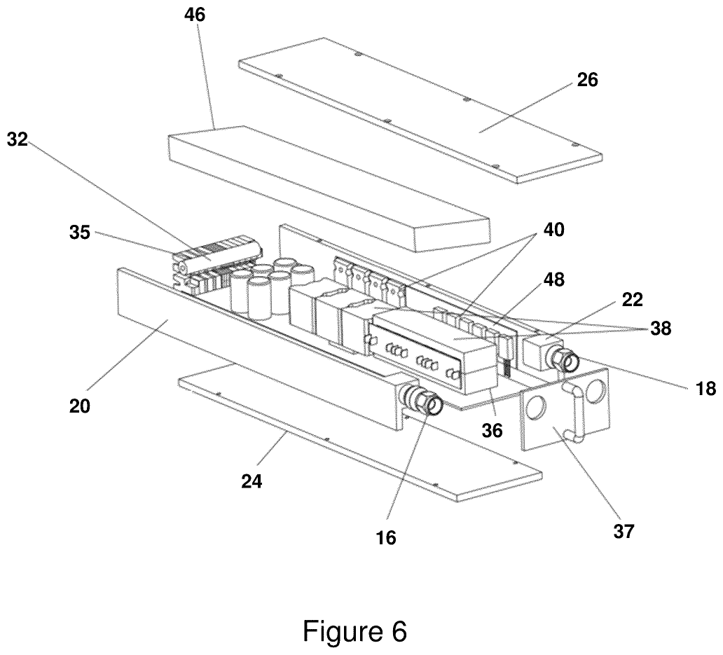

FIG. 6 illustrates an exploded view of the interior of the power supply unit in accordance with various embodiments of the present disclosure. As shown in FIG. 6, a left cold plate 20 and a right cold plate 22 are secured to a housing floor (bottom case portion 24) and a housing ceiling (top case portion 26) using corresponding floor screws and ceiling screws. A connecting channel 32 runs transversely at the rear end of the housing. An inlet 16 is placed at an upper portion of the left cold plate 20. An outlet 18 is placed at an upper portion of the right cold plate 22. The front end 37 of the housing includes two openings through which the inlet 16 and the outlet 18 respectively extend to the exterior of the housing. As shown in FIG. 6, a handle is mounted on the front end 37.

Throughout the description, the left cold plate 20 may be alternatively referred to as a first sidewall portion or a left sidewall portion of the housing. The right cold plate 22 may be alternatively referred to as a second sidewall portion or a right sidewall portion of the housing.

A printed-circuit board assembly 36 is placed inside the housing. The printed-circuit board assembly 36 supports various components that require cooling. These components include magnetic components 38, typically inductors and transformers. Semiconductor components 40 are mounted on the left cold plate 20 or the right cold plate 22. In other words, the semiconductor components 40 are thermally connected to either the left cold plate 20 or the right cold plate 22. The cold plates are able to efficiently absorb the heat generated by the semiconductor components 40.

In some embodiments, thermal communication between the heat generating components (e.g., magnetic components 38 and semiconductor components 40) and the cold plates 20, 22 is enhanced by thermally-conductive adhesive 46 and thermal interface material (TIM) pads 48. These materials reduce interfacial thermal resistance and improve heat conduction to the cold plates 20 and 22.

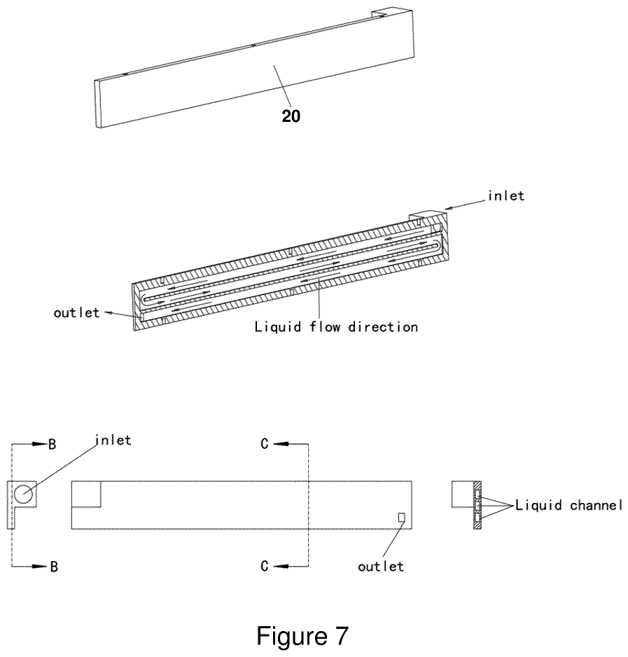

FIG. 7 illustrates a cutaway view of the left cold plate in accordance with various embodiments of the present disclosure. The left cold plate 20 has an interior wall facing the interior of the power supply unit and an exterior wall facing the exterior of the power supply unit. The upper portion of FIG. 7 shows a perspective view of the left cold plate 20. The middle portion of FIG. 7 shows a cutaway view of the left cold plate 20 taken along line B-B. The cutaway view shows an intramural channel running inside the left cold plate 20, allowing fluid communication between a first plate inlet and a first plate outlet. The first plate outlet is connected to the right cold plate 22 through the connecting channel 32. In some embodiments, the intramural channel follows a meandering or serpentine path through the left cold plate 20, causing the coolant to flow in alternating directions (as indicated by arrows in FIG. 7) within the left cold plate 20. The bottom right corner of FIG. 7 shows a cross-sectional view of the left cold plate 20 along line C-C.

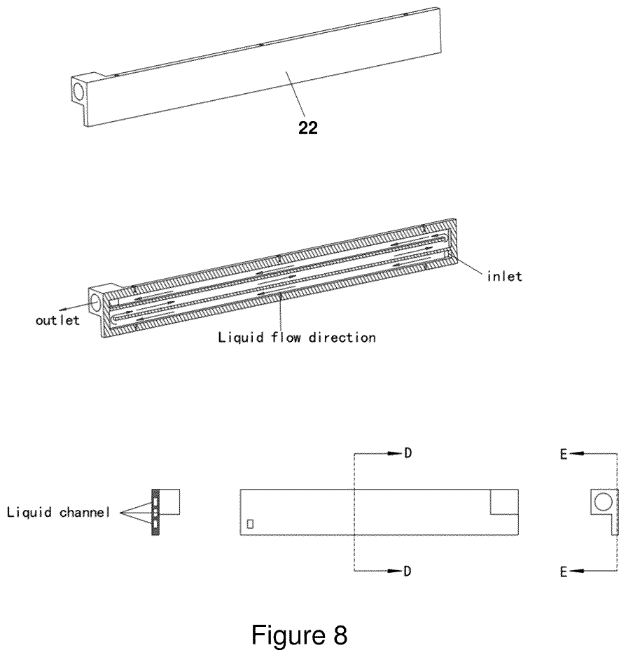

FIG. 8 illustrates a cutaway view of the right cold plate in accordance with various embodiments of the present disclosure. The right cold plate 22 has an interior wall facing the interior of the power supply unit and an exterior wall facing the exterior of the power supply unit. The upper portion of FIG. 8 shows a perspective view of the right cold plate 22. The middle portion of FIG. 8 shows a cutaway view of the right cold plate along line E-E. The cutaway view shows an intramural channel running inside the right cold plate, allowing fluid communication between a second plate inlet and a second plate outlet. The second plate inlet is connected to the first plate outlet shown in FIG. 7 through the connecting channel 32. In some embodiments, the intramural channel follows a meandering or serpentine path through the right cold plate 22, causing the coolant to flow in alternating directions (as indicated by arrows in FIG. 8) within the right cold plate 22. The bottom left corner of FIG. 8 shows a cross-sectional view of the right cold plate 22 along line D-D.

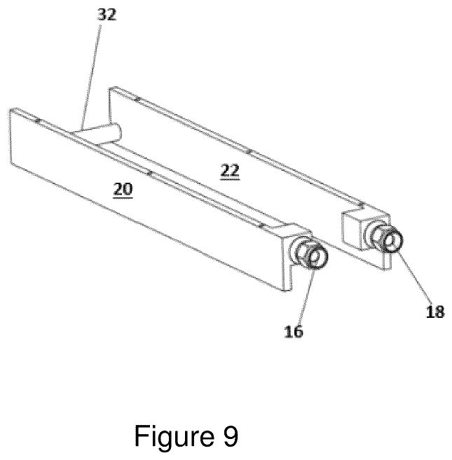

FIG. 9 illustrates a perspective view of the cold plates in accordance with various embodiments of the present disclosure. The first and second cold plates 20, 22 have similar structures. The first and second cold plates 20, 22 are preferably made of a material having high thermal conductivity. Suitable examples include metals, such as aluminum and alloys thereof.

As shown in FIG. 9, the connecting channel 32 connects the first and second cold plates 20 and 22.

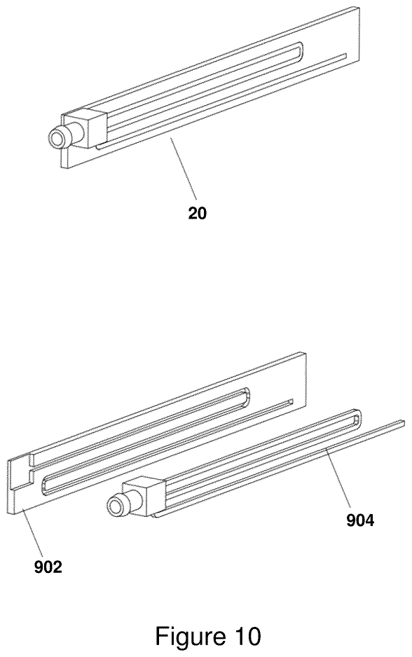

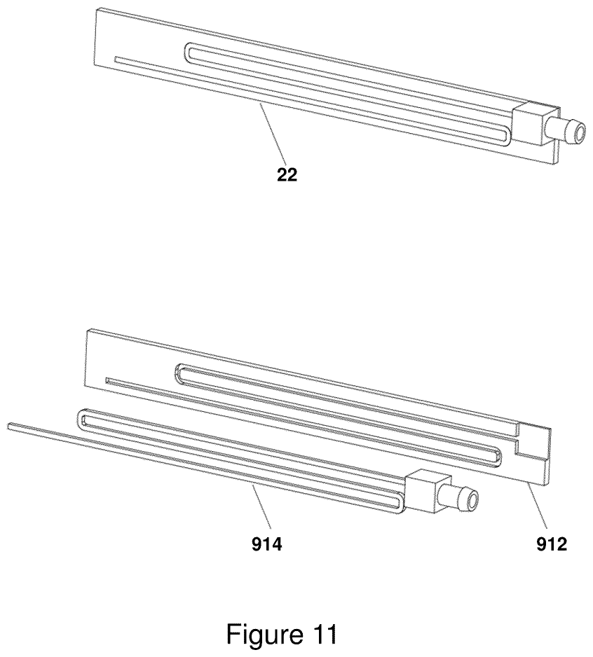

FIG. 10 illustrates an implementation of the left cold plate in accordance with various embodiments of the present disclosure. FIG. 11 illustrates an implementation of the right cold plate in accordance with various embodiments of the present disclosure. The left cold plate 20 comprises a left cold plate substrate 902 and a left copper tube 904. The right cold plate 22 comprises a right cold plate substrate 912 and a right copper tube 914. As shown in FIG. 10, the left cold plate substrate 902 comprises a first meandering trench. The left copper tube 904 is a meandering copper tube embedded in the first meandering trench to form the first meandering channel. As shown in FIG. 11, the right cold plate substrate 912 comprises a second meandering trench. The right copper tube 914 is a meandering copper tube embedded in the second meandering trench to form the second meandering channel. In operation, coolant flows through the first meandering channel and the second meandering channel, and further flows into the outlet after absorbing heat generated by the heat generating components. It should be noted that although FIG. 10 does not depict a connecting channel, one of ordinary skill in the art will understand that a connecting channel may be provided to establish a liquid flowing path between the left cold plate 20 and the right cold plate 22.

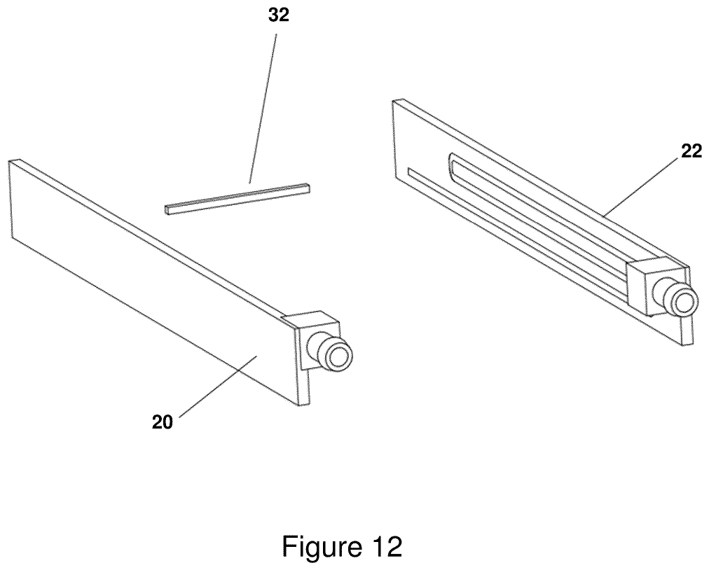

FIG. 12 illustrates a connecting channel placed between the left cold plate and the right cold plate in accordance with various embodiments of the present disclosure. The first sidewall portion 20 comprises a first meandering channel connected to an inlet. The second sidewall portion 22 comprises a second meandering channel connected to an outlet. The connecting channel 32 is connected between the first meandering channel and the second meandering channel. The coolant flows through the first meandering channel, the connecting channel and the second meandering channel and into the outlet to absorb heat generated by the heat generating components.

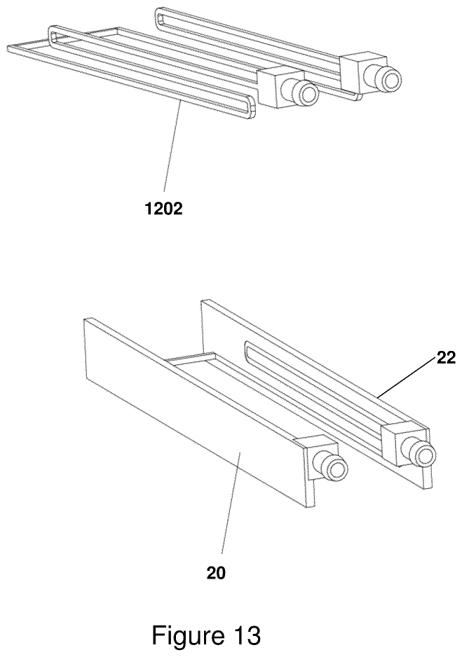

FIG. 13 illustrates an integrated tube in accordance with various embodiments of the present disclosure. As shown in FIG. 13, the first sidewall portion 20 comprises a first meandering trench. The second sidewall portion 22 comprises a second meandering trench. An integrated copper tube 1202 includes a first meandering copper tube portion embedded in the first meandering trench, a second meandering copper tube portion embedded in the second meandering trench and a connecting portion to form a liquid flowing channel to absorb heat generated by the heat generating components.

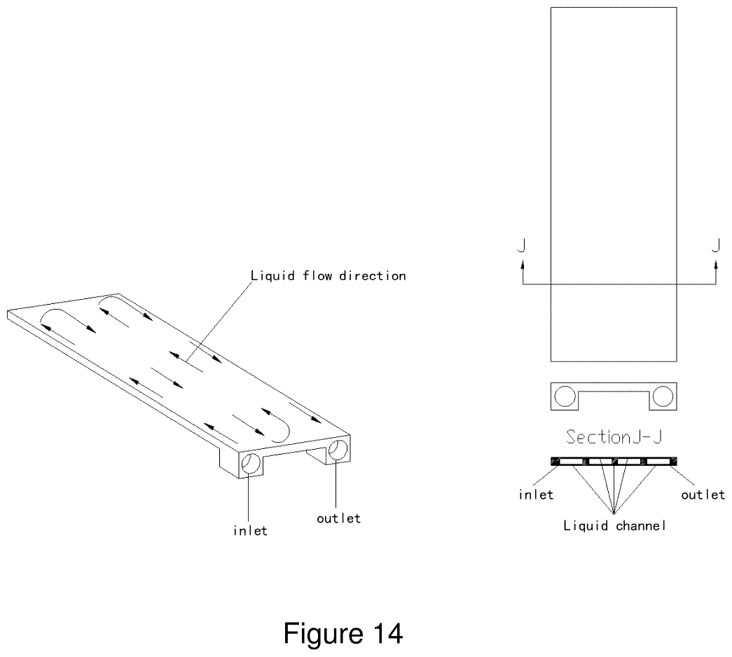

FIG. 14 illustrates a top case portion of the housing in accordance with various embodiments of the present disclosure. The top case portion comprises a meandering channel connected between an inlet and an outlet. As shown in FIG. 14, the inlet is adjacent to a leftmost corner of the top case portion. The outlet is adjacent to a rightmost corner of the top case portion. The right bottom corner of FIG. 14 shows a cross-sectional view of the top case portion along line J-J.

In operation, the coolant flows through the liquid channel from the inlet to the outlet to absorb heat generated by the heat generating components.

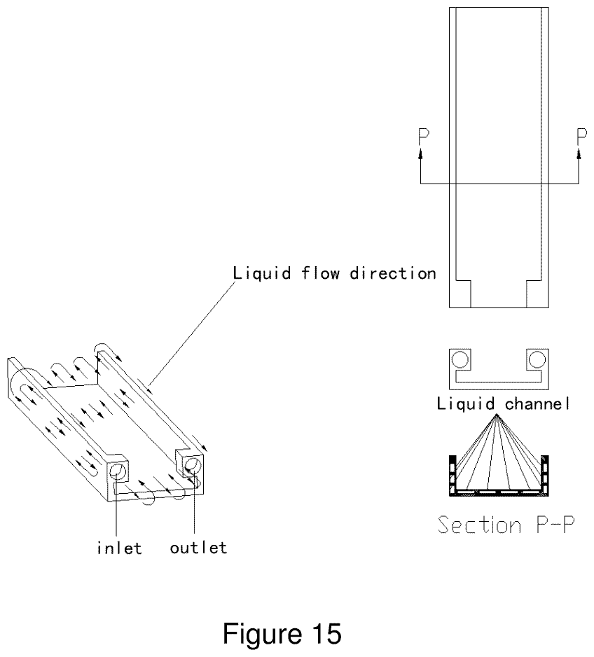

FIG. 15 illustrates a bottom case portion and two sidewall portions of the housing in accordance with various embodiments of the present disclosure. The left sidewall portion comprises a left meandering channel. The input of the left meandering channel is connected to the inlet. The bottom case portion comprises a bottom meandering channel. The input of the bottom meandering channel is connected to an output of the left meandering channel. The right sidewall portion comprises a right meandering channel. The input of the right meandering channel is connected to an output of the bottom meandering channel. The output of the right meandering channel is connected to the outlet. As illustrated in FIG. 15, the arrows indicate the direction of liquid flow. In operation, the coolant enters through the inlet, first passes through the left meandering channel, then flows through the bottom meandering channel, subsequently proceeds through the right meandering channel, and finally exits at the outlet to absorb heat generated by the heat generating components.

As shown in FIG. 15, the inlet is at an upper portion of the left sidewall portion. The outlet is at an upper portion of the right sidewall portion. The right bottom corner of FIG. 15 shows a cross-sectional view of the bottom case portion and the two sidewall portions along line P-P. The cross-sectional view shows that the meandering channels are in the bottom case portion and the two sidewall portions.

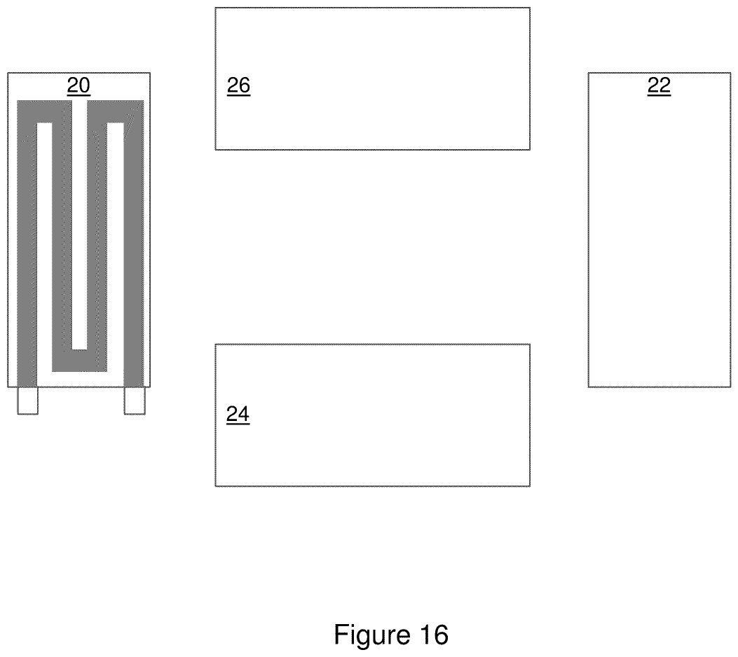

FIGS. 16-26 illustrate various cooling implementations of the housing in accordance with various embodiments of the present disclosure. For clarity in depicting the liquid channels, the first sidewall portion 20, the second sidewall portion 22, the bottom case portion 24 and the top case portion 26 are shown laid out on a common plane. In actual use, these four portions are assembled to form the housing of the power supply unit, as shown in earlier figures (e.g., FIG. 6).

FIG. 16 illustrates a first cooling implementation of the housing in accordance with various embodiments of the present disclosure. The first sidewall portion 20 comprises a first meandering channel connected between a first inlet and a first outlet. The first inlet is adjacent to a topmost corner of the first sidewall portion. The first outlet is adjacent to a bottommost corner of the first sidewall portion. The first inlet and the first outlet are placed adjacent to the front end of the housing. The electrical connectors are placed on the rear end of the housing. In operation, the first meandering channel is configured to provide thermal communication with the heat generating components. More particularly, coolant flowing from the first inlet to the first outlet absorbs heat generated by the heat generating components.

It should be noted that while FIG. 16 shows the meandering channel is in the first sidewall portion 20, depending on design needs, a similar meandering channel may be formed in the second sidewall portion 22.

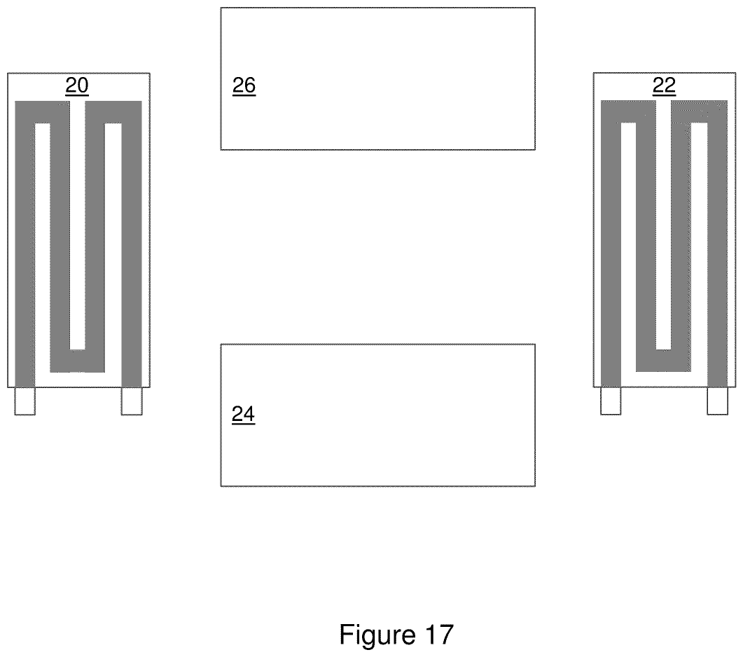

FIG. 17 illustrates a second cooling implementation of the housing in accordance with various embodiments of the present disclosure. The first sidewall portion 20 comprises a first meandering channel connected between a first inlet and a first outlet. The first inlet is adjacent to a topmost corner of the first sidewall portion. The first outlet is adjacent to a bottommost corner of the first sidewall portion. The second sidewall portion 22 comprises a second meandering channel connected between a second inlet and a second outlet. The second inlet is adjacent to a topmost corner of the second sidewall portion. The second outlet is adjacent to a bottommost corner of the second sidewall portion. The first meandering channel and the second meandering channel are configured to provide thermal communication with the heat generating components.

In the second cooling implementation, the first inlet, the first outlet, the second inlet and the second outlet are placed adjacent to the front end of the housing. The electrical connectors are placed on the rear end of the housing.

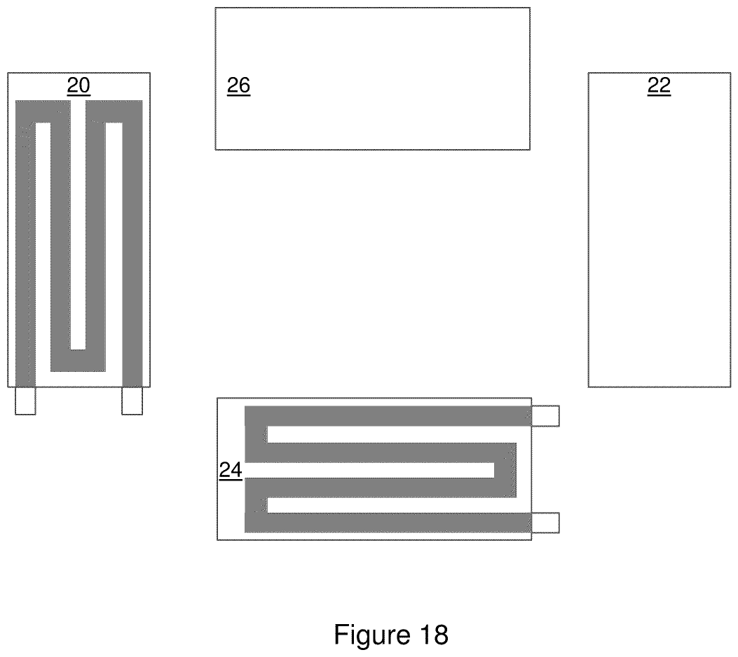

FIG. 18 illustrates a third cooling implementation of the housing in accordance with various embodiments of the present disclosure. The first sidewall portion 20 comprises a first meandering channel connected between a first inlet and a first outlet. The first inlet is adjacent to a topmost corner of the first sidewall portion. The first outlet is adjacent to a bottommost corner of the first sidewall portion. The bottom case portion 24 comprises a third meandering channel connected between a third inlet and a third outlet. The third inlet is adjacent to a leftmost corner of the bottom case portion. The third outlet is adjacent to a rightmost corner of the bottom case portion. The first meandering channel and the third meandering channel are configured to provide thermal communication with the heat generating components.

In the third cooling implementation, the first inlet, the first outlet, the third inlet and the third outlet are placed adjacent to the front end of the housing. The electrical connectors are placed on the rear end of the housing.

It should be noted that, while FIG. 18 illustrates a cooling combination comprising a meandering channel in the first sidewall portion 20 and a meandering channel in the bottom case portion 24, the sidewall meandering channel may, depending on design requirements, instead be formed in the second sidewall portion 22.

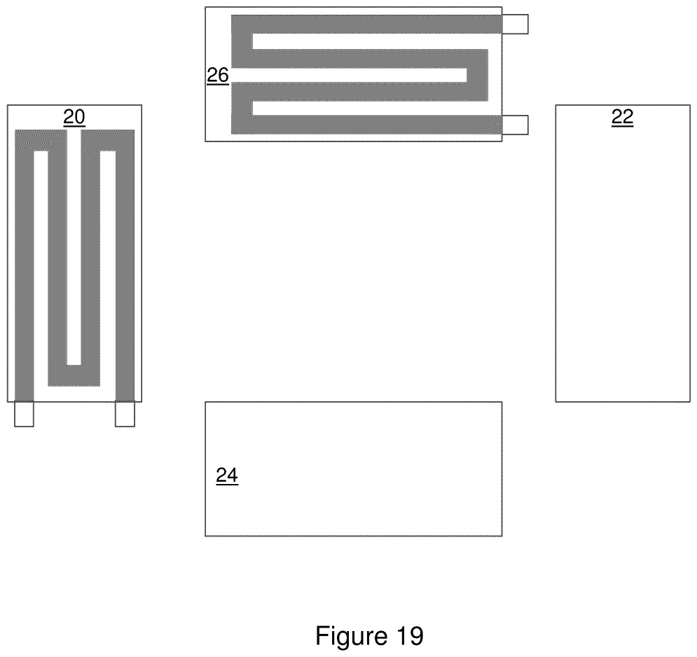

FIG. 19 illustrates a fourth cooling implementation of the housing in accordance with various embodiments of the present disclosure. The first sidewall portion 20 comprises a first meandering channel connected between a first inlet and a first outlet. The first inlet is adjacent to a topmost corner of the first sidewall portion. The first outlet is adjacent to a bottommost corner of the first sidewall portion. The top case portion 26 comprises a fourth meandering channel connected between a fourth inlet and a fourth outlet. The fourth inlet is adjacent to a leftmost corner of the top case portion. The fourth outlet is adjacent to a rightmost corner of the top case portion. The first meandering channel and the fourth meandering channel are configured to provide thermal communication with the heat generating components.

In the fourth cooling implementation, the first inlet, the first outlet, the fourth inlet and the fourth outlet are placed adjacent to the front end of the housing. The electrical connectors are placed on the rear end of the housing.

It should be noted that, while FIG. 19 illustrates a cooling combination comprising a meandering channel in the first sidewall portion 20 and a meandering channel in the top case portion 26, the sidewall meandering channel may, depending on design requirements, instead be formed in the second sidewall portion 22.

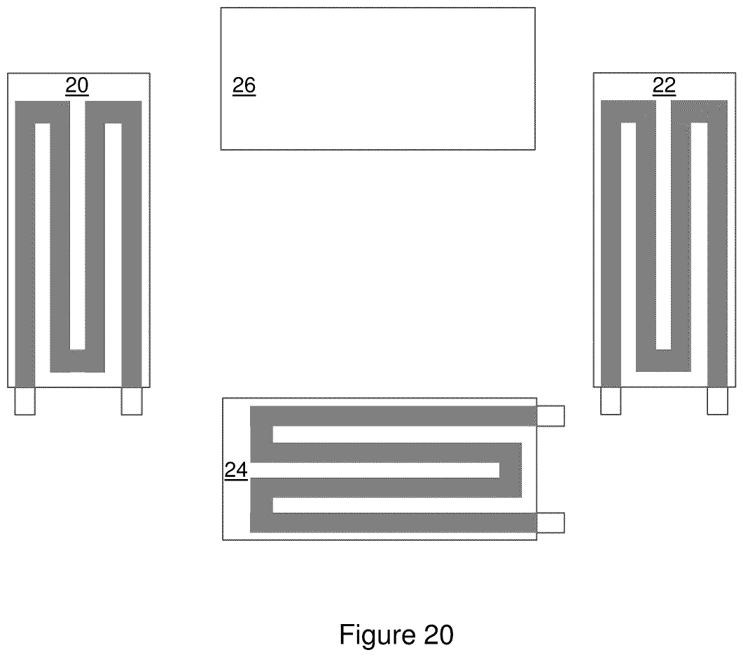

FIG. 20 illustrates a fifth cooling implementation of the housing in accordance with various embodiments of the present disclosure. The first sidewall portion 20 comprises a first meandering channel connected between a first inlet and a first outlet. The first inlet is adjacent to a topmost corner of the first sidewall portion. The first outlet is adjacent to a bottommost corner of the first sidewall portion. The second sidewall portion 22 comprises a second meandering channel connected between a second inlet and a second outlet. The second inlet is adjacent to a topmost corner of the second sidewall portion. The second outlet is adjacent to a bottommost corner of the second sidewall portion. The bottom case portion 24 comprises a third meandering channel connected between a third inlet and a third outlet. The third inlet is adjacent to a leftmost corner of the bottom case portion. The third outlet is adjacent to a rightmost corner of the bottom case portion. The first meandering channel, the second meandering channel and the third meandering channel are configured to provide thermal communication with the heat generating components.

In the fifth cooling implementation, the first inlet, the first outlet, the second inlet, the second outlet, the third inlet and the third outlet are placed adjacent to the front end of the housing. The electrical connectors are placed on the rear end of the housing.

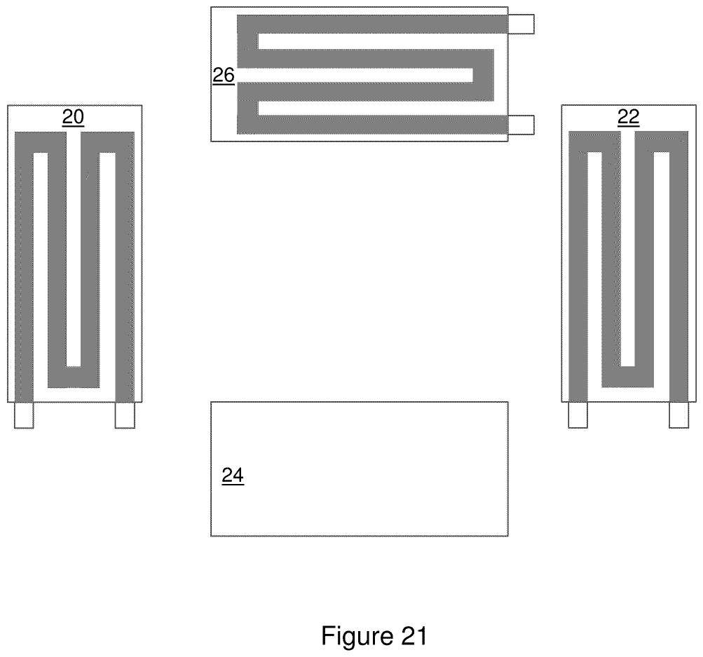

FIG. 21 illustrates a sixth cooling implementation of the housing in accordance with various embodiments of the present disclosure. The first sidewall portion 20 comprises a first meandering channel connected between a first inlet and a first outlet. The first inlet is adjacent to a topmost corner of the first sidewall portion. The first outlet is adjacent to a bottommost corner of the first sidewall portion. The second sidewall portion 22 comprises a second meandering channel connected between a second inlet and a second outlet. The second inlet is adjacent to a topmost corner of the second sidewall portion. The second outlet is adjacent to a bottommost corner of the second sidewall portion. The top case portion 26 comprises a fourth meandering channel connected between a fourth inlet and a fourth outlet. The fourth inlet is adjacent to a leftmost corner of the top case portion. The fourth outlet is adjacent to a rightmost corner of the top case portion. The first meandering channel, the second meandering channel and the fourth meandering channel are configured to provide thermal communication with the heat generating components.

In the sixth cooling implementation, the first inlet, the first outlet, the second inlet, the second outlet, the fourth inlet and the fourth outlet are placed adjacent to the front end of the housing. The electrical connectors are placed on the rear end of the housing.

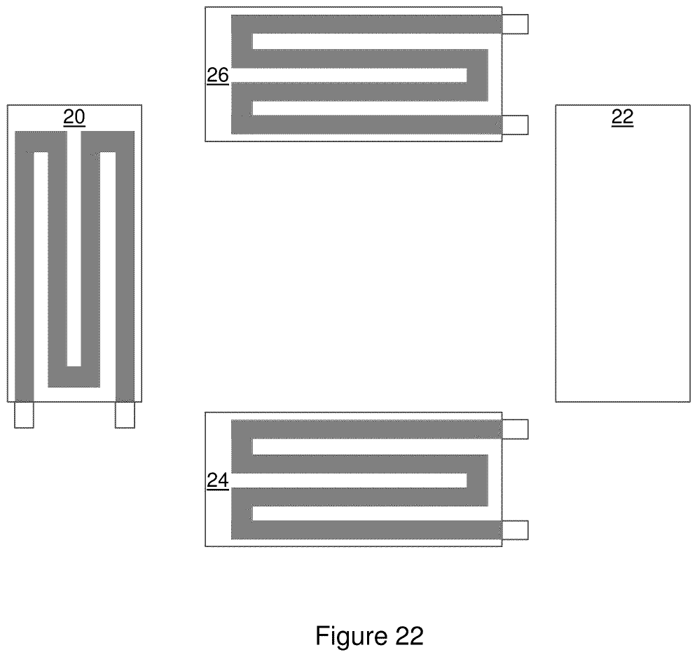

FIG. 22 illustrates a seventh cooling implementation of the housing in accordance with various embodiments of the present disclosure. The first sidewall portion 20 comprises a first meandering channel connected between a first inlet and a first outlet. The first inlet is adjacent to a topmost corner of the first sidewall portion. The first outlet is adjacent to a bottommost corner of the first sidewall portion. The bottom case portion 24 comprises a third meandering channel connected between a third inlet and a third outlet. The third inlet is adjacent to a leftmost corner of the bottom case portion. The third outlet is adjacent to a rightmost corner of the bottom case portion. The top case portion 26 comprises a fourth meandering channel connected between a fourth inlet and a fourth outlet. The fourth inlet is adjacent to a leftmost corner of the top case portion. The fourth outlet is adjacent to a rightmost corner of the top case portion. The first meandering channel, the third meandering channel and the fourth meandering channel are configured to provide thermal communication with the heat generating components.

In the seventh cooling implementation, the first inlet, the first outlet, the third inlet, the third outlet, the fourth inlet and the fourth outlet are placed adjacent to the front end of the housing. The electrical connectors are placed on the rear end of the housing.

It should be noted that, while FIG. 22 illustrates a cooling combination comprising a meandering channel in the first sidewall portion 20 and meandering channels in the bottom and top case portions, the sidewall meandering channel may, depending on design requirements, instead be formed in the second sidewall portion 22.

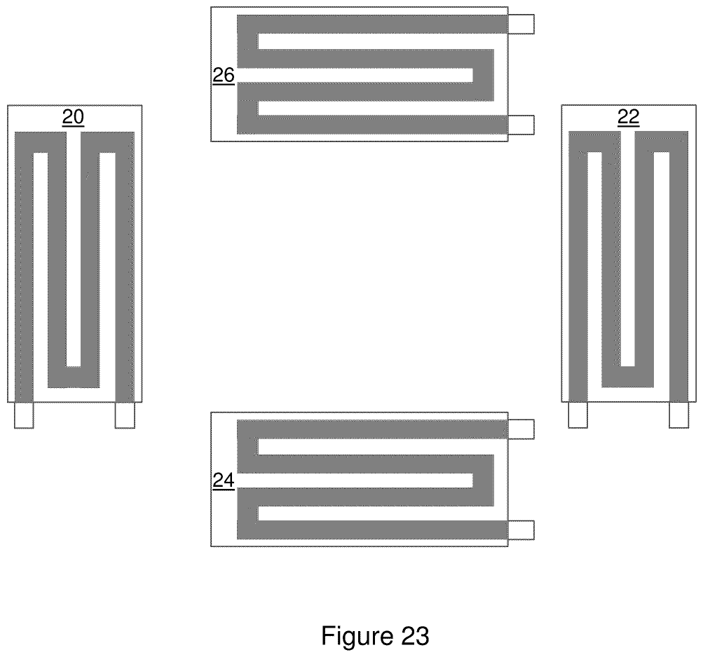

FIG. 23 illustrates an eighth cooling implementation of the housing in accordance with various embodiments of the present disclosure. The first sidewall portion 20 comprises a first meandering channel connected between a first inlet and a first outlet. The first inlet is adjacent to a topmost corner of the first sidewall portion. The first outlet is adjacent to a bottommost corner of the first sidewall portion. The second sidewall portion 22 comprises a second meandering channel connected between a second inlet and a second outlet. The second inlet is adjacent to a topmost corner of the second sidewall portion. The second outlet is adjacent to a bottommost corner of the second sidewall portion. The bottom case portion 24 comprises a third meandering channel connected between a third inlet and a third outlet. The third inlet is adjacent to a leftmost corner of the bottom case portion. The third outlet is adjacent to a rightmost corner of the bottom case portion. The top case portion 26 comprises a fourth meandering channel connected between a fourth inlet and a fourth outlet. The fourth inlet is adjacent to a leftmost corner of the top case portion. The fourth outlet is adjacent to a rightmost corner of the top case portion. The first meandering channel, the second meandering channel, the third meandering channel and the fourth meandering channel are configured to provide thermal communication with the heat generating components.

In the eighth cooling implementation, the first inlet, the first outlet, the second inlet, the second outlet, the third inlet, the third outlet, the fourth inlet and the fourth outlet are placed adjacent to the front end of the housing. The electrical connectors are placed on the rear end of the housing.

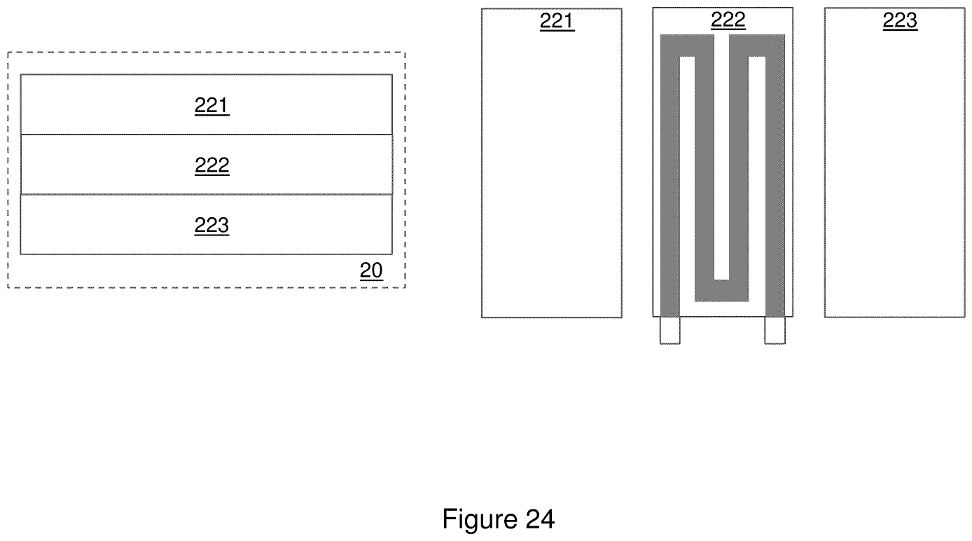

FIG. 24 illustrates a first implementation of the sidewall portion in accordance with various embodiments of the present disclosure. The first sidewall portion 20 is used as an example to illustrate the first implementation. As shown in FIG. 24, the first sidewall portion 20 comprises a first layer 221, a second layer 222 and a third layer 223. As shown in FIG. 24, the first layer 221 is in direct contact with the second layer 222, and the second layer 222 is in direct contact with the third layer 223. The first layer is formed of aluminum and functions as an interior sidewall. The second layer is formed of copper and comprises a meandering channel extending between an inlet and an outlet. The meandering channel is configured to provide thermal communication with the heat generating components. The third layer is formed of aluminum and functions as an exterior sidewall.

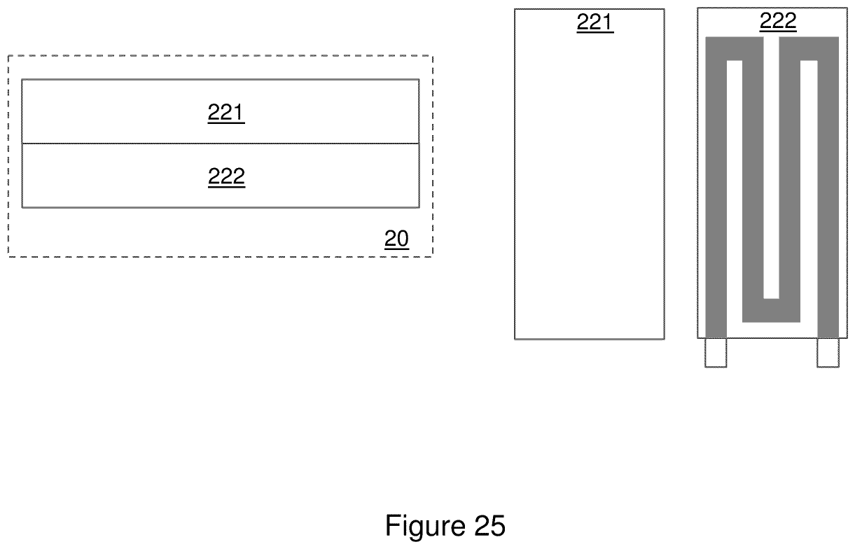

FIG. 25 illustrates a second implementation of the sidewall portion in accordance with various embodiments of the present disclosure. The first sidewall portion 20 is used as an example to illustrate the second implementation. As shown in FIG. 25, the first sidewall portion 20 comprises a first layer 221 and a second layer 222. As shown in FIG. 25, the first layer 221 is in direct contact with the second layer 222. The first layer is formed of aluminum and functions as an interior sidewall. The second layer is formed of copper and functions as an exterior sidewall. The second layer comprises a meandering channel extending between an inlet and an outlet. The meandering channel is configured to provide thermal communication with the heat generating components.

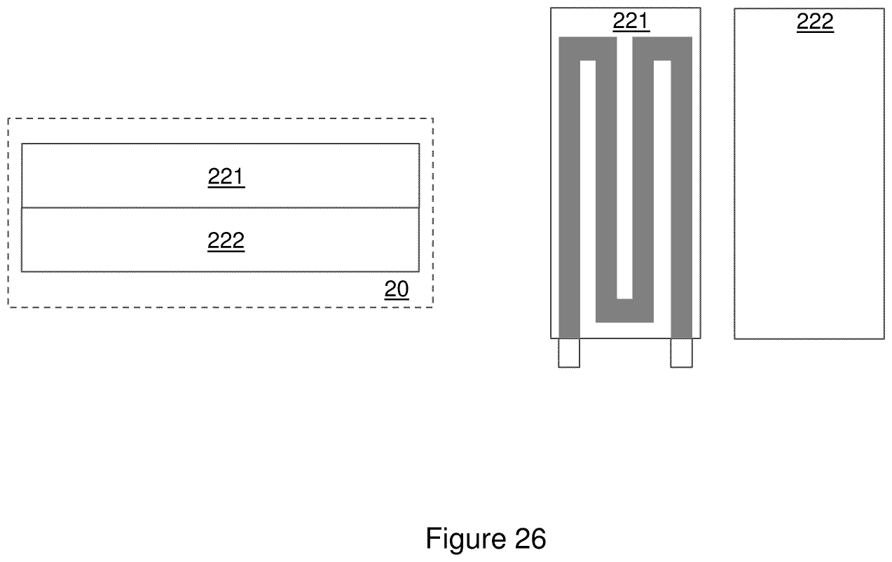

FIG. 26 illustrates a third implementation of the sidewall portion in accordance with various embodiments of the present disclosure. The first sidewall portion 20 is used as an example to illustrate the third implementation. As shown in FIG. 26, the first sidewall portion 20 comprises a first layer 221 and a second layer 222. As shown in FIG. 26, the first layer 221 is in direct contact with the second layer 222. The first layer is formed of copper and functions as an interior sidewall. The first layer comprises a meandering channel extending between an inlet and an outlet. The meandering channel is configured to provide thermal communication with the heat generating components. The second layer is formed of aluminum and functions as an exterior sidewall.

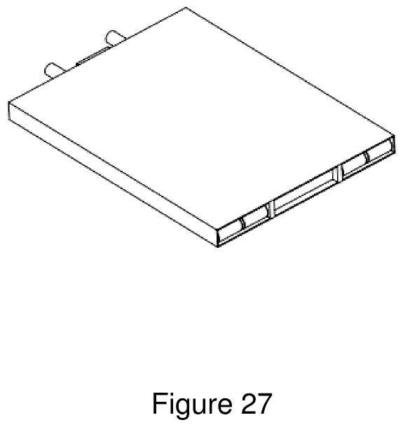

FIG. 27 is a perspective view of a power shelf in accordance with various embodiments of the present disclosure. The power shelf provides mechanical support and liquid-cooling integration for multiple power modules and capacitor modules.

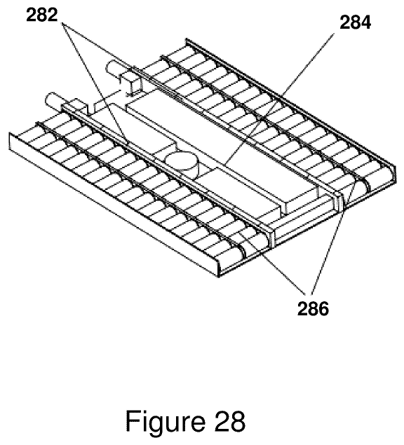

FIG. 28 is a perspective view of the power shelf after the top case has been removed in accordance with various embodiments of the present disclosure. As shown in FIG. 28, the power shelf includes a power supply unit 284 and two hybrid capacitor modules 286. The power supply unit 284 is positioned between the two capacitor modules 286. A liquid-cooled sidewall structure 282 is arranged between the capacitor modules 286 and the power supply unit 284. The liquid-cooled sidewall structure 282 defines two thermally conductive sidewalls that form part of a liquid-cooling path similar to that described in the preceding embodiments. The coolant flows through internal channels of the liquid-cooled sidewall structure 282 to absorb heat from both the power supply unit 284 and the capacitor modules 286, thereby providing effective thermal management for the entire shelf assembly.

It should be understood that all embodiments of the liquid-cooled structures described above are applicable to the liquid-cooled sidewall structure 282 shown in FIG. 28. For example, the embodiments illustrated in FIGS. 10 and 11, which include meandering copper tubes embedded in corresponding trenches, may be applied to form the liquid-cooled sidewall structure 282. Likewise, the embodiments shown in FIGS. 12 and 13, which employ connecting channels or integrated tubes between opposite sidewalls, are also applicable to the liquid-cooled sidewall structure 282. In some embodiments, the liquid-cooled sidewall structure 282 may alternatively be replaced by the top case portion illustrated in FIG. 14 or the bottom case portion illustrated in FIG. 15 to achieve similar cooling functionality. Furthermore, any of the cooling implementations described in FIGS. 16-25 may be employed in the liquid-cooled sidewall structure 282 to provide thermal communication with adjacent power and capacitor modules.

It should further be noted that the arrangement of one power supply unit 284 and two hybrid capacitor modules 286 shown in FIG. 28 is merely illustrative. Depending on application requirements and design needs, the power shelf may incorporate additional power supply units and/or a greater number of energy-storage modules (e.g., hybrid capacitor modules) arranged in series and/or parallel banks. In all such variations, the liquid-cooled sidewall structure 282 is disposed to surround or laterally bound the power supply unit 284. For example, the liquid-cooled sidewall structure 282 provides opposing thermally conductive sidewalls adjacent the power supply unit, thereby maintaining the liquid-cooling functionality and thermal communication described herein.

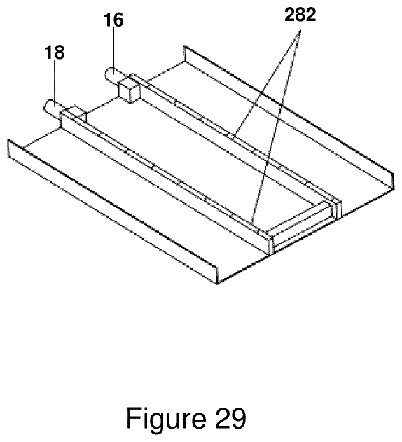

FIG. 29 is a perspective view of the power shelf after all components except the liquid-cooled sidewall structure have been removed in accordance with various embodiments of the present disclosure. FIG. 29 shows that the liquid-cooled sidewall structure 282 includes a pair of parallel sidewalls extending along the longitudinal direction of the shelf. A liquid inlet 16 and a liquid outlet 18 are positioned at the front portion of the shelf to enable circulation of coolant through the internal channels of the sidewall structure 282.

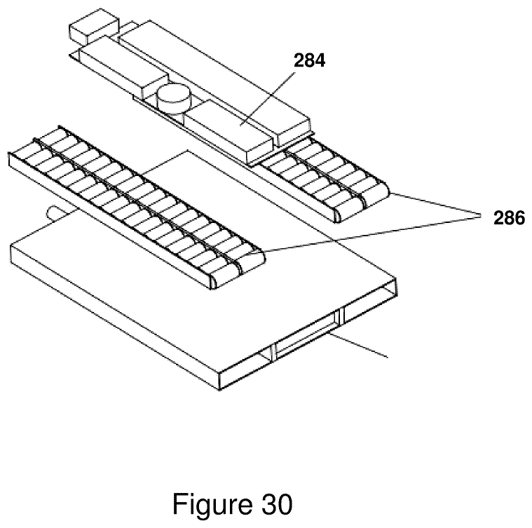

FIG. 30 is an exploded view of the power shelf in accordance with various embodiments of the present disclosure. The exploded view shows the relative placement of the power supply unit 284, the hybrid capacitor modules 286, and the liquid-cooled sidewall structure 282 within the shelf housing. In assembly, the liquid-cooled sidewall structure 282 is sandwiched between the power supply unit 284 and the hybrid capacitor modules 286, thereby forming thermal interfaces on both sides. The integrated configuration provides compact packaging, efficient heat dissipation, and enhanced reliability for high-power applications such as data center power delivery systems.

Although embodiments of the present disclosure and its advantages have been described in detail, it should be understood that various changes, substitutions and alterations can be made herein without departing from the spirit and scope of the disclosure as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A system comprising:
a power conversion system configured to be connected between a power source and a load, wherein the power conversion system is connected to the power source through a first interface, and the power conversion system is connected to the load through a second interface; and
a housing comprising a front side portion, a rear side portion, a first sidewall portion, a second sidewall portion, a bottom case portion and a top case portion, wherein:
the power conversion system is placed inside the housing;
at least one of the first sidewall portion, the second sidewall portion, the bottom case portion and the top case portion comprises a channel through which coolant flows to cool heat generating components of the power conversion system;
liquid interface ports are placed adjacent to the front side portion; and
the first interface and the second interface are placed adjacent to the rear side portion.

2. The system of claim 1, further comprising a connecting channel, wherein:
the first sidewall portion comprises a first meandering channel connected to a liquid inlet;
the second sidewall portion comprises a second meandering channel connected to a liquid outlet; and
the connecting channel is connected between the first meandering channel and the second meandering channel such that coolant flows through the first meandering channel, the connecting channel and the second meandering channel to absorb heat generated by the heat generating components.

3. The system of claim 2, wherein:
the first sidewall portion comprises a first meandering trench and a first meandering copper tube, and wherein the first meandering copper tube is embedded in the first meandering trench to form the first meandering channel; and
the second sidewall portion comprises a second meandering trench and a second meandering copper tube, and wherein the second meandering copper tube is embedded in the second meandering trench to form the second meandering channel.

4. The system of claim 2, wherein:
the first sidewall portion comprises a first meandering trench;
the second sidewall portion comprises a second meandering trench; and
an integrated copper tube includes a first meandering copper tube portion embedded in the first meandering trench, a second meandering copper tube portion embedded in the second meandering trench and a connecting portion, and wherein the first meandering copper tube portion, the connecting portion and the second meandering copper tube portion form the channel.

5. The system of claim 2, wherein:
the top case portion comprises a meandering channel connected between a liquid inlet and a liquid outlet, and wherein the liquid inlet is adjacent to a leftmost corner of the top case portion, and the liquid outlet is adjacent to a rightmost corner of the top case portion.

6. The system of claim 2, wherein:
the first sidewall portion comprises a first meandering channel;
the second sidewall portion comprises a second meandering channel; and
the bottom case portion comprises a bottom meandering channel, and wherein:
an input of the first meandering channel is connected to a liquid inlet;
an input of the bottom meandering channel is connected to an output of the first meandering channel;
an input of the second meandering channel is connected to an output of the bottom meandering channel; and
an output of the second meandering channel is connected to a liquid outlet.

7. The system of claim 1, wherein:
the first sidewall portion comprises a first meandering channel connected between a first inlet and a first outlet, and wherein the first inlet is adjacent to a topmost corner of the first sidewall portion, and the first outlet is adjacent to a bottommost corner of the first sidewall portion, and wherein the first meandering channel is configured to provide thermal communication with the heat generating components, and wherein the first inlet and the first outlet are placed adjacent to the front side portion of the housing.

8. The system of claim 1, wherein:
the first sidewall portion comprises a first meandering channel connected between a first inlet and a first outlet, and wherein the first inlet is adjacent to a topmost corner of the first sidewall portion, and the first outlet is adjacent to a bottommost corner of the first sidewall portion; and
the second sidewall portion comprises a second meandering channel connected between a second inlet and a second outlet, and wherein the second inlet is adjacent to a topmost corner of the second sidewall portion, and the second outlet is adjacent to a bottommost corner of the second sidewall portion, and wherein the first meandering channel and the second meandering channel are configured to provide thermal communication with the heat generating components, and wherein the first inlet, the first outlet, the second inlet and the second outlet are placed adjacent to the front side portion of the housing.

9. The system of claim 1, wherein:
the first sidewall portion comprises a first meandering channel connected between a first inlet and a first outlet, and wherein the first inlet is adjacent to a topmost corner of the first sidewall portion, and the first outlet is adjacent to a bottommost corner of the first sidewall portion; and
the bottom case portion comprises a third meandering channel connected between a third inlet and a third outlet, and wherein the third inlet is adjacent to a leftmost corner of the bottom case portion, and the third outlet is adjacent to a rightmost corner of the bottom case portion, and wherein the first meandering channel and the third meandering channel are configured to provide thermal communication with the heat generating components, and wherein the first inlet, the first outlet, the third inlet and the third outlet are placed adjacent to the front side portion of the housing.

10. The system of claim 1, wherein:
the first sidewall portion comprises a first meandering channel connected between a first inlet and a first outlet, and wherein the first inlet is adjacent to a topmost corner of the first sidewall portion, and the first outlet is adjacent to a bottommost corner of the first sidewall portion; and
the top case portion comprises a fourth meandering channel connected between a fourth inlet and a fourth outlet, and wherein the fourth inlet is adjacent to a leftmost corner of the top case portion, and the fourth outlet is adjacent to a rightmost corner of the top case portion, and wherein the first meandering channel and the fourth meandering channel are configured to provide thermal communication with the heat generating components, and wherein the first inlet, the first outlet, the fourth inlet and the fourth outlet are placed adjacent to the front side portion of the housing.

11. The system of claim 1, wherein:
the first sidewall portion comprises a first meandering channel connected between a first inlet and a first outlet, and wherein the first inlet is adjacent to a topmost corner of the first sidewall portion, and the first outlet is adjacent to a bottommost corner of the first sidewall portion;
the second sidewall portion comprises a second meandering channel connected between a second inlet and a second outlet, and wherein the second inlet is adjacent to a topmost corner of the second sidewall portion, and the second outlet is adjacent to a bottommost corner of the second sidewall portion; and
the bottom case portion comprises a third meandering channel connected between a third inlet and a third outlet, and wherein the third inlet is adjacent to a leftmost corner of the bottom case portion, and the third outlet is adjacent to a rightmost corner of the bottom case portion, and wherein the first meandering channel, the second meandering channel and the third meandering channel are configured to provide thermal communication with the heat generating components, and wherein the first inlet, the first outlet, the second inlet, the second outlet, the third inlet and the third outlet are placed adjacent to the front side portion of the housing.

12. The system of claim 1, wherein:
the first sidewall portion comprises a first meandering channel connected between a first inlet and a first outlet, and wherein the first inlet is adjacent to a topmost corner of the first sidewall portion, and the first outlet is adjacent to a bottommost corner of the first sidewall portion;
the second sidewall portion comprises a second meandering channel connected between a second inlet and a second outlet, and wherein the second inlet is adjacent to a topmost corner of the second sidewall portion, and the second outlet is adjacent to a bottommost corner of the second sidewall portion; and
the top case portion comprises a fourth meandering channel connected between a fourth inlet and a fourth outlet, and wherein the fourth inlet is adjacent to a leftmost corner of the top case portion, and the fourth outlet is adjacent to a rightmost corner of the top case portion, and wherein the first meandering channel, the second meandering channel and the fourth meandering channel are configured to provide thermal communication with the heat generating components, and wherein the first inlet, the first outlet, the second inlet, the second outlet, the fourth inlet and the fourth outlet are placed adjacent to the front side portion of the housing.

13. The system of claim 1, wherein:
the first sidewall portion comprises a first meandering channel connected between a first inlet and a first outlet, and wherein the first inlet is adjacent to a topmost corner of the first sidewall portion, and the first outlet is adjacent to a bottommost corner of the first sidewall portion;
the bottom case portion comprises a third meandering channel connected between a third inlet and a third outlet, and wherein the third inlet is adjacent to a leftmost corner of the bottom case portion, and the third outlet is adjacent to a rightmost corner of the bottom case portion; and
the top case portion comprises a fourth meandering channel connected between a fourth inlet and a fourth outlet, and wherein the fourth inlet is adjacent to a leftmost corner of the top case portion, and the fourth outlet is adjacent to a rightmost corner of the top case portion, and wherein the first meandering channel, the third meandering channel and the fourth meandering channel are configured to provide thermal communication with the heat generating components, and wherein the first inlet, the first outlet, the third inlet, the third outlet, the fourth inlet and the fourth outlet are placed adjacent to the front side portion of the housing.

14. The system of claim 1, wherein:
the first sidewall portion comprises a first meandering channel connected between a first inlet and a first outlet, and wherein the first inlet is adjacent to a topmost corner of the first sidewall portion, and the first outlet is adjacent to a bottommost corner of the first sidewall portion;
the second sidewall portion comprises a second meandering channel connected between a second inlet and a second outlet, and wherein the second inlet is adjacent to a topmost corner of the second sidewall portion, and the second outlet is adjacent to a bottommost corner of the second sidewall portion;
the bottom case portion comprises a third meandering channel connected between a third inlet and a third outlet, and wherein the third inlet is adjacent to a leftmost corner of the bottom case portion, and the third outlet is adjacent to a rightmost corner of the bottom case portion; and
the top case portion comprises a fourth meandering channel connected between a fourth inlet and a fourth outlet, and wherein the fourth inlet is adjacent to a leftmost corner of the top case portion, and the fourth outlet is adjacent to a rightmost corner of the top case portion, and wherein the first meandering channel, the second meandering channel, the third meandering channel and the fourth meandering channel are configured to provide thermal communication with the heat generating components, and wherein the first inlet, the first outlet, the second inlet, the second outlet, the third inlet, the third outlet, the fourth inlet and the fourth outlet are placed adjacent to the front side portion of the housing.

15. A power shelf comprising:
a power supply unit configured to convert electrical power between a power source and a load;
at least two capacitor modules disposed adjacent to the power supply unit; and
a liquid-cooled sidewall structure positioned between the power supply unit and each of the capacitor modules, the liquid-cooled sidewall structure comprising two parallel sidewalls each having an internal coolant channel configured to absorb heat generated by the power supply unit and the capacitor modules.

16. The power shelf of claim 15, wherein:
the liquid-cooled sidewall structure includes a liquid inlet and a liquid outlet arranged at a front side portion of the power shelf and fluidly coupled to the internal coolant channels to permit coolant circulation through the liquid-cooled sidewall structure.

17. The power shelf of claim 15, wherein:
the liquid-cooled sidewall structure is thermally coupled to the power supply unit on a first side and to the capacitor modules on an opposite side, and the coolant channels are configured to provide thermal communication with both the power supply unit and the capacitor modules.

18. The power shelf of claim 15, wherein the liquid-cooled sidewall structure comprises:
a first meandering channel formed in a first sidewall and connected to an inlet;
a second meandering channel formed in a second sidewall and connected to an outlet; and
a connecting channel connected between the first meandering channel and the second meandering channel, wherein:
the inlet and the outlet are placed adjacent to a front side portion of the power shelf; and
the connecting channel is placed adjacent to a rear side portion of the power shelf.

19. A liquid-cooled power supply unit comprising:
a power conversion system comprising a plurality of magnetic devices, a plurality of power switches, wherein the power conversion system is connected to a power source through a first electrical connector, and the power conversion system is connected to a load through a second electrical connector; and
a housing comprising a front side portion, a rear side portion, a first sidewall portion, a second sidewall portion, a bottom case portion and a top case portion, wherein:
the power conversion system is placed inside the housing;
at least one of the first sidewall portion, the second sidewall portion, the bottom case portion and the top case portion comprises a channel through which coolant flows to cool the plurality of magnetic devices and the plurality of power switches;
a liquid inlet and a liquid outlet are placed adjacent to the front side portion; and
the first electrical connector and the second electrical connector are placed adjacent to the rear side portion.

20. The liquid-cooled power supply unit of claim 19, further comprising:
a connecting channel, wherein:
the liquid inlet is connected to the first sidewall portion;
the first sidewall portion comprises a first meandering channel connected to the liquid inlet;
the liquid outlet is connected to the second sidewall portion; and
the second sidewall portion comprises a second meandering channel connected to the liquid outlet, and wherein the connecting channel is connected between the first meandering channel and the second meandering channel such that coolant flows through the first meandering channel, the connecting channel and the second meandering channel to absorb heat generated by the plurality of magnetic devices and the plurality of power switches.
